(19) United States
(12) Patent Application Publication
(10) Pub. No.: US 2017/0024075 A1
(43) Pub. Date: Jan. 26, 2017

(54) IN-CELL TOUCH PANEL

(71) Applicant: Raydium Semiconductor Corporation, Hsinchu (TW)

(72) Inventors: Chang-Ching Chiang, Taichung City (TW); Yi-Ying Lin, Hualien City (TW); Kun-Pei Lee, Miaoli County (TW)

(21) Appl. No.: 15/206,548

(22) Filed: Jul. 11, 2016

Related U.S. Application Data
(60) Provisional application No. 62/194,709, filed on Jul. 20, 2015.

(51) Int. Cl. G06F 3/041; H01L 27/32; G06F 3/044

(52) U.S. Cl. CPC G06F 3/0418; G06F 3/0412; G06F 3/044; H01L 27/3246; H01L 27/323; G06F 2203/04111; H01L 51/5284

(57) ABSTRACT

An in-cell touch panel is disclosed. The in-cell touch panel includes a plurality of pixels. A laminated structure of each pixel includes a substrate, an organic emissive layer, a spacer and a first conductive layer. The organic emissive layer is formed above the substrate. The spacer is formed above the substrate with a specific distribution density. The first conductive layer is formed above the organic emissive layer opposite to the substrate, wherein at least a part of the first conductive layer is not formed above the spacer.

### BACKGROUND OF THE INVENTION

1. Field of the invention

This invention relates to a touch panel, especially to an in-cell touch panel.

2. Description of the prior art

In general, capacitive touch panels using active matrix organic light emitting diode (AMOLED) display technology can be divided into different types based on their different laminated structures, such as in-cell AMOLED capacitive touch panels and on-cell AMOLED capacitive touch panels.

Please refer to FIG. 1 and FIG. 2. FIG. 1 and FIG. 2 illuminate schematic diagrams of the laminated structures of the on-cell AMOLED capacitive touch panel and the in-cell AMOLED capacitive touch panel respectively. As shown in FIG. 1, the laminated structure 1 of the on-cell AMOLED capacitive touch panel includes a substrate 10, an AMOLED layer 11, an encapsulation layer 12, a touch sensing layer 13, a polarizer 14, an adhesive 15 and a top cover lens 16 from the bottom up. As shown in FIG. 2, the laminated structure 2 of the in-cell AMOLED capacitive touch panel includes a substrate 20, an AMOLED layer 21, a touch sensing layer 22, an encapsulation layer 23, a polarizer 24, an adhesive 25 and a top cover lens 26 from the bottom up.

After comparing FIG. 1 with FIG. 2, it can be found that the touch sensing layer 22 of the in-cell AMOLED capacitive touch panel is disposed under the encapsulation layer 23, namely the touch sensing layer 22 is disposed in the AMOLED display module; the touch sensing layer 13 of the on-cell AMOLED capacitive touch panel is disposed above the encapsulation layer 12, namely the touch sensing layer 13 is disposed out of the AMOLED display module. Compared to the conventional one glass solution (OGS) AMOLED capacitive touch panel and the on-cell AMOLED capacitive touch panel, the in-cell AMOLED capacitive touch panel can achieve the thinnest AMOLED touch panel design and it can be widely used in portable electronic products such as cell phones, tablet PCs and notebook PCs.

Please also refer to FIG. 3 and FIG. 4. FIG. 3 and FIG. 4 illuminate schematic diagrams of the larger parasitic capacitance generated in the overlapped area of the touch sensing electrode and the spacer. As shown in FIG. 3, the conductive layer M1 is disposed on the lower surface of the encapsulation layer ENC and the cathode layer CA covers the spacer SP. Since the spacer SP has its own height, the cathode layer CA covering on the spacer SP will be raised by the spacer SP and the distance between the cathode layer CA and the conductive layer M1 above will become smaller. This will cause larger parasitic capacitance C generated in the overlapped area of the conductive layer M1 and the spacer SP; therefore, the RC loading of the in-cell touch panel will be largely increased and the touch performance of the in-cell touch panel will be also affected.

Similarly, as shown in FIG. 4, the conductive layer M1 is disposed on the lower surface of the encapsulation layer ENC, the conductive layer M2 is disposed on the lower surface of the conductive layer M1, and the cathode layer CA covers the spacer SP. Since the spacer SP has its own height, the cathode layer CA covering on the spacer SP will be raised by the spacer SP and the distance between the cathode layer CA and the conductive layer M2 above will become smaller. This will cause larger parasitic capacitance C generated in the overlapped area of the conductive layer M2 and the spacer SP; therefore, the RC loading of the in-cell touch panel will be largely increased and the touch performance of the in-cell touch panel will be also affected.

### SUMMARY OF THE INVENTION

Therefore, the invention provides an in-cell touch panel having novel layout to simplify the design of circuit traces and reduce the effects of resistance and parasitic capacitance to solve the above-mentioned problems and enhance the entire performance of the in-cell touch panel.

A preferred embodiment of the invention is an in-cell touch panel. In this embodiment, the in-cell touch panel includes a plurality of pixels. A laminated structure of each pixel includes a substrate, an organic emissive layer, a spacer and a first conductive layer. The organic emissive layer is formed above the substrate. The spacer is formed above the substrate with a specific distribution density. The first conductive layer is formed above the organic emissive layer opposite to the substrate, wherein at least a part of the first conductive layer is not formed above the spacer.

In an embodiment, the in-cell touch panel is an in-cell self-capacitive touch panel or an in-cell mutual-capacitive touch panel.

In an embodiment, the first conductive layer is formed after the spacer.

In an embodiment, the first conductive layer is formed by transparent conductive material.

In an embodiment, the first conductive layer is used as a cathode of the organic emissive layer.

In an embodiment, a part of the first conductive layer formed above the spacer is separated from the first conductive layer used as the cathode of the organic emissive layer and maintained in a floating state.

In an embodiment, the first conductive layer is used as a touch sensing electrode of the in-cell touch panel.

In an embodiment, a part of the first conductive layer formed above the spacer is separated from the first conductive layer used as the touch sensing electrode of the in-cell touch panel and maintained in a floating state.

In an embodiment, the in-cell touch panel includes an encapsulation layer formed above the organic emissive layer and the spacer opposite to the substrate, wherein the first conductive layer is formed on the encapsulation layer.

In an embodiment, the in-cell touch panel includes an encapsulation layer and a second conductive layer. The encapsulation layer is formed above the organic emissive layer and the spacer opposite to the substrate. The second conductive layer is formed on the encapsulation layer.

In an embodiment, the second conductive layer is used as a touch sensing electrode of the in-cell touch panel.

In an embodiment, the second conductive layer is formed by transparent conductive material.

In an embodiment, at least a part of the second conductive layer is not formed above the spacer.

In an embodiment, the second conductive layer is formed above the spacer.

In an embodiment, the in-cell touch panel includes a light-blocking layer formed on the encapsulation layer and a third conductive layer formed under the light-blocking layer.

In an embodiment, the third conductive layer is coupled to the second conductive layer and used as traces of the touch sensing electrode.

In an embodiment, an insulating layer is formed between the second conductive layer and the third conductive layer.

In an embodiment, the second conductive layer and the third conductive layer are electrically connected through a via formed in the insulating layer.

In an embodiment, there is no insulating layer between the second conductive layer and the third conductive layer, and the second conductive layer and the third conductive layer are electrically connected through a direct contacting way.

In an embodiment, the second conductive layer and the third conductive layer are not electrically connected.

In an embodiment, the light-blocking layer is formed above the spacer.

In an embodiment, the second conductive layer and the third conductive layer are also formed above the spacer.

In an embodiment, at least a part of the light-blocking layer is not formed above the spacer.

In an embodiment, at least a part of the third conductive layer is not formed above the spacer.

In an embodiment, at least a part of the second conductive layer is not formed above the spacer.

In an embodiment, at least a part of the third conductive layer is routed bypassing the spacer.

In an embodiment, at least a part of the second conductive layer and the third conductive layer is removed to reduce a RC loading of the in-cell touch panel.

Compared to the prior art, the in-cell touch panel of the invention has the following advantages and effects:

(1) The designs of touch electrodes and their traces are simple.

(2) The original aspect ratio of the in-cell touch panel is not affected by the layout of the invention.

(3) The RC loading of the touch electrodes can be effectively reduced.

(4) The module thickness of the AMOLED touch panel can be effectively reduced.

The advantage and spirit of the invention may be understood by the following detailed descriptions together with the appended drawings.

### BRIEF DESCRIPTION OF THE APPENDED DRAWINGS

FIG. 1 and FIG. 2 illuminate schematic diagrams of the laminated structures of the on-cell AMOLED capacitive touch panel and the in-cell AMOLED capacitive touch panel respectively.

FIG. 3 and FIG. 4 illuminate schematic diagrams of the larger parasitic capacitance generated in the overlapped area of the touch sensing electrode and the spacer.

FIG. 5 illuminates the first embodiment of the laminated structure of the pixel of the in-cell touch panel of the invention.

FIG. 6 illuminates the second embodiment of the laminated structure of the pixel of the in-cell touch panel of the invention.

FIG. 7 illuminates the third embodiment of the laminated structure of the pixel of the in-cell touch panel of the invention.

FIG. 8 illuminates the fourth embodiment of the laminated structure of the pixel of the in-cell touch panel of the invention.

FIG. 9 illuminates the fifth embodiment of the laminated structure of the pixel of the in-cell touch panel of the invention.

FIG. 10 illuminates the sixth embodiment of the laminated structure of the pixel of the in-cell touch panel of the invention.

FIG. 11 and FIG. 12 illuminate different layout ways of traces in the in-cell touch panel of the invention respectively.

FIG. 13 illuminates the seventh embodiment of the laminated structure of the pixel of the in-cell touch panel of the invention.

FIG. 14 illuminates the eighth embodiment of the laminated structure of the pixel of the in-cell touch panel of the invention.

FIG. 15 illuminates another layout way of traces in the in-cell touch panel of the invention.

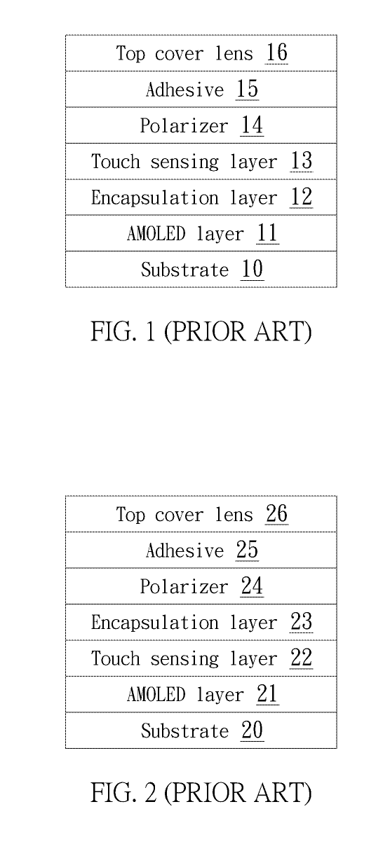

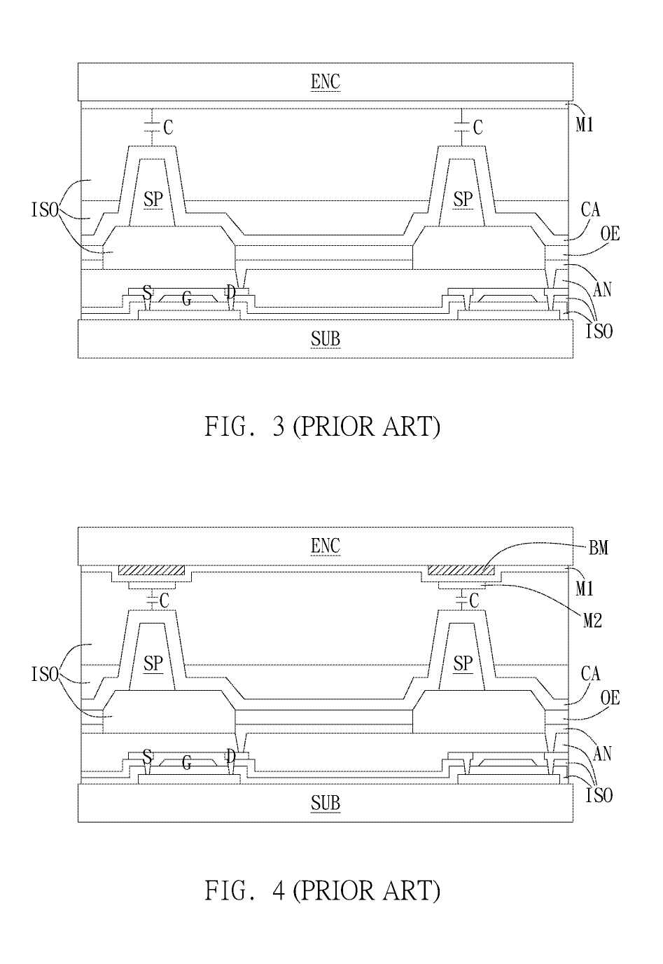

### DETAILED DESCRIPTION OF THE INVENTION

The invention discloses an in-cell touch panel. In practical applications, the in-cell touch panel of the invention can be an in-cell self-capacitive touch panel or an on-cell self-capacitive touch panel without any specific limitations. The in-cell touch panel includes a plurality of pixels. The actual design of the in-cell touch panel can be designed in different ways based on different panels and characteristics. For example, the invention can be practiced in the in-cell touch panels having the laminated structure including white-light OLED and color filtering layer or other laminated structures without any specific limitations.

A laminated structure of each pixel in the in-cell touch panel of the invention includes a substrate, an organic emissive layer, a spacer and a first conductive layer. Wherein, the organic emissive layer is formed above the substrate; the spacer is formed above the substrate with a specific distribution density; the first conductive layer is formed above the organic emissive layer opposite to the substrate. The first conductive layer is formed by transparent conductive material and the first conductive layer is formed after the spacer. In fact, the spacer can be used to support the fine metal mask in manufacturing process or to separate the substrate and the above encapsulation layer to generate a fixed distance between the substrate and the encapsulation layer. The organic emissive layer can include an active-matrix organic light-emitting diode (AMOLED), but not limited to this.

It should be noticed that, in this invention, the first conductive layer can be the touch sensing electrode or the cathode of the organic emissive layer. At least a part of the first conductive layer is not formed above the spacer. That is to say, the first conductive layer formed above the organic emissive layer opposite to the substrate in the invention will not be all formed above the spacer. Instead, at least a part of the first conductive layer or even the entire first conductive layer will not be formed above the spacer.

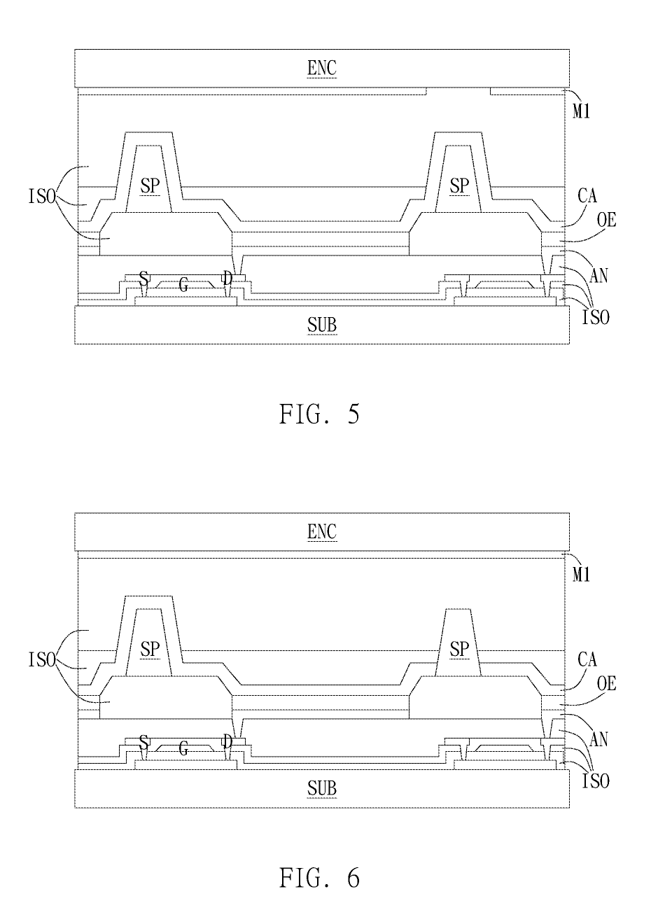

At first, please refer to FIG. 5. FIG. 5 illuminates the first embodiment of the laminated structure of the pixel of the in-cell touch panel of the invention.

As shown in FIG. 5, the laminated structure 5 includes a substrate SUB, an OLED layer OE, an encapsulation layer ENC, a spacer SP, a conductive layer M1, an anode layer AN, a cathode layer CA and an insulating layer ISO. Wherein, the OLED layer OE is disposed above the substrate SUB. The encapsulation layer ENC is disposed above the OLED layer OE opposite to the substrate SUB. The conductive layer M1 is disposed on the lower surface of the encapsulation layer ENC and used as the touch sensing electrode of the in-cell touch panel. The anode layer AN and the cathode layer CA are disposed under and above the OLED layer OE respectively and used as the anode and the cathode of the OLED layer OE respectively.

It should be noticed that, in the laminated structure 5 of this embodiment, the touch sensing electrode overlapping the spacer SP at the right side (namely the conductive layer M1 disposed above the spacer SP at the right side) has been removed, and the touch sensing electrode overlapping the spacer SP at the left side (namely the conductive layer M1 disposed above the spacer SP at the left side) has been maintained, but not limited to this. The cathode layer CA entirely covers the spacer SP at both the right side and the left side; that is to say, the cathode layer CA and the spacer SP at both the right side and the left side are overlapped. Since the conductive layer M1 disposed above the spacer SP at the right side has been removed, the parasitic capacitance between the conductive layer M1 and the cathode layer CA generated above the spacer SP at the right side in the prior arts can be effectively avoided in this embodiment; therefore, the RC loading of the in-cell touch panel can be effectively reduced and the touch performance of the in-cell touch panel can be also enhanced. As to the spacer SP at the left side, it is used as a control group of generating the parasitic capacitance. In fact, the conductive layer M1 disposed above the spacer SP at the left side can be also removed to achieve better parasitic capacitance reducing effect, but not limited to this.

Then, please refer to FIG. 6. FIG. 6 illuminates the second embodiment of the laminated structure of the pixel of the in-cell touch panel of the invention.

As shown in FIG. 6, the laminated structure 6 includes a substrate SUB, an OLED layer OE, an encapsulation layer ENC, a spacer SP, a conductive layer M1, an anode layer AN, a cathode layer CA and an insulating layer ISO. Wherein, the OLED layer OE is disposed above the substrate SUB. The encapsulation layer ENC is disposed above the OLED layer OE opposite to the substrate SUB. The conductive layer M1 is disposed on the lower surface of the encapsulation layer ENC and used as the touch sensing electrode of the in-cell touch panel. The anode layer AN and the cathode layer CA are disposed under and above the OLED layer OE respectively and used as the anode and the cathode of the OLED layer OE respectively.

It should be noticed that, in the laminated structure 6 of this embodiment, the cathode layer CA overlapping the spacer SP at the right side has been removed (namely the spacer SP at the right side is not covered by the cathode layer CA) and the cathode layer CA overlapping the spacer SP at the left side has been maintained (namely the spacer SP at the left side is still covered by the cathode layer CA), but not limited to this.

The conductive layer M1 used as the touch sensing electrodes is entirely disposed on the lower surface of the encapsulation layer ENC; that is to say, the conductive layer M1 is disposed above the spacer SP at both the right side and the left side. Since the cathode layer CA disposed above the spacer SP at the right side has been removed, the parasitic capacitance between the conductive layer M1 and the cathode layer CA generated above the spacer SP at the right side in the prior arts can be effectively avoided in this embodiment; therefore, the RC loading of the in-cell touch panel can be effectively reduced and the touch performance of the in-cell touch panel can be also enhanced. As to the spacer SP at the left side, it is used as a control group of generating the parasitic capacitance. In fact, the cathode layer CA disposed above the spacer SP at the left side can be also removed to achieve better parasitic capacitance reducing effect, but not limited to this.

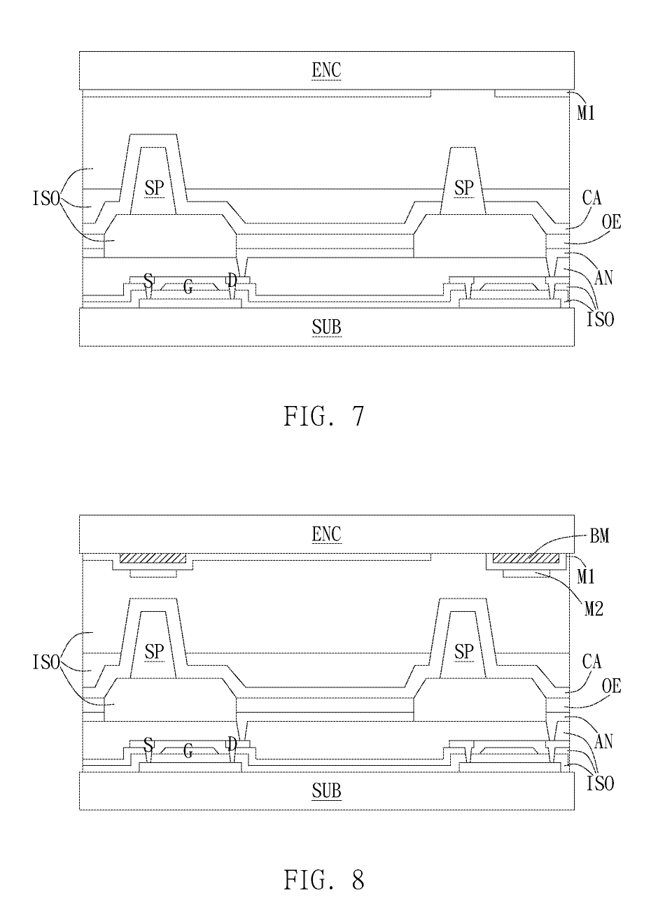

Please refer to FIG. 7. FIG. 7 illuminates the third embodiment of the laminated structure of the pixel of the in-cell touch panel of the invention.

As shown in FIG. 7, the laminated structure 7 includes a substrate SUB, an OLED layer OE, an encapsulation layer ENC, a spacer SP, a conductive layer M1, an anode layer AN, a cathode layer CA and an insulating layer ISO. Wherein, the OLED layer OE is disposed above the substrate SUB. The encapsulation layer ENC is disposed above the OLED layer OE opposite to the substrate SUB. The conductive layer M1 is disposed on the lower surface of the encapsulation layer ENC and used as the touch sensing electrode of the in-cell touch panel. The anode layer AN and the cathode layer CA are disposed under and above the OLED layer OE respectively and used as the anode and the cathode of the OLED layer OE respectively.

It should be noticed that, in the laminated structure 7 of this embodiment, the cathode layer CA overlapping the spacer SP and the conductive layer M1 used as the touch sensing electrodes at the right side have been removed (namely the spacer SP at the right side is not covered by the cathode layer CA and no conductive layer M1 is disposed above the spacer SP at the right side) and the cathode layer CA overlapping the spacer SP at the left side has been maintained (namely the spacer SP at the left side is still covered by the cathode layer CA and the conductive layer M1 is still disposed above the spacer SP at the left side), but not limited to this. Since the cathode layer CA and the conductive layer M1 disposed above the spacer SP at the right side have been removed, the parasitic capacitance between the conductive layer M1 and the cathode layer CA generated above the spacer SP at the right side in the prior arts can be effectively avoided in this embodiment; therefore, the RC loading of the in-cell touch panel can be effectively reduced and the touch performance of the in-cell touch panel can be also enhanced. As to the spacer SP at the left side, it is used as a control group of generating the parasitic capacitance. In fact, the cathode layer CA and the conductive layer M1 disposed above the spacer SP at the left side can be also removed to achieve better parasitic capacitance reducing effect, but not limited to this.

Please refer to FIG. 8. FIG. 8 illuminates the fourth embodiment of the laminated structure of the pixel of the in-cell touch panel of the invention.

As shown in FIG. 8, the laminated structure 8 includes a substrate SUB, an OLED layer OE, an encapsulation layer ENC, a spacer SP, a conductive layer M1, an anode layer AN, a cathode layer CA, an insulating layer ISO, a conductive layer M2 and a light-blocking layer BM. Wherein, the OLED layer OE is disposed above the substrate SUB. The encapsulation layer ENC is disposed above the OLED layer OE opposite to the substrate SUB. The conductive layer M1 is disposed on the lower surface of the encapsulation layer ENC and used as the touch sensing electrode of the in-cell touch panel. The anode layer AN and the cathode layer CA are disposed under and above the OLED layer OE respectively and used as the anode and the cathode of the OLED layer OE respectively. The light-blocking layer BM is disposed between the encapsulation layer ENC and the conductive layer M1; the conductive layer M2 is disposed on the lower surface of the conductive layer M1 and under the light-blocking layer BM, so that the conductive layer M2 can be shielded by the light-blocking layer BM. Since the conductive layer M2 is shielded by the light-blocking layer BM, the conductive layer M2 can be formed by transparent conductive material or opaque conductive material without specific limitations. The conductive layer M2 is coupled to the conductive layer M1 and used as traces of the touch sensing electrodes.

It should be noticed that, in the laminated structure 8 of this embodiment, the conductive layer M1 disposed above the spacer SP at the right side has been removed and the conductive layer M2 is not disposed above the spacer SP at the right side, the conductive layer M1 disposed above the spacer SP at the left side has been maintained and the conductive layer M2 is disposed above the spacer SP at the left side, but not limited to this. The cathode layer CA entirely covers the spacer SP at the right side and the left side, namely the cathode layer CA and the spacer SP at the right side and the left side are overlapped. Since the conductive layer M1 disposed above the spacer SP at the right side have been removed and the conductive layer M2 is not disposed above the spacer SP at the right side, the parasitic capacitance between the conductive layer M2 and the cathode layer CA generated above the spacer SP at the right side in the prior arts can be effectively avoided in this embodiment; therefore, the RC loading of the in-cell touch panel can be effectively reduced and the touch performance of the in-cell touch panel can be also enhanced. As to the spacer SP at the left side, it is used as a control group of generating the parasitic capacitance. In fact, the conductive layer M1 disposed above the spacer SP at the left side can be also removed and the conductive layer M2 can be routed bypassing the spacer SP at the left side to achieve better parasitic capacitance reducing effect, but not limited to this.

In practical applications, there can be an insulating layer formed between the conductive layer M1 and the conductive layer M2, and the conductive layer M1 and the conductive layer M2 are electrically connected through a via formed in the insulating layer. In addition, there can be no insulating layer between the conductive layer M1 and the conductive layer M2, and the conductive layer M1 and the conductive layer M2 can be electrically connected through a direct contacting way. Furthermore, the conductive layer M1 and the conductive layer M2 can be not electrically connected.

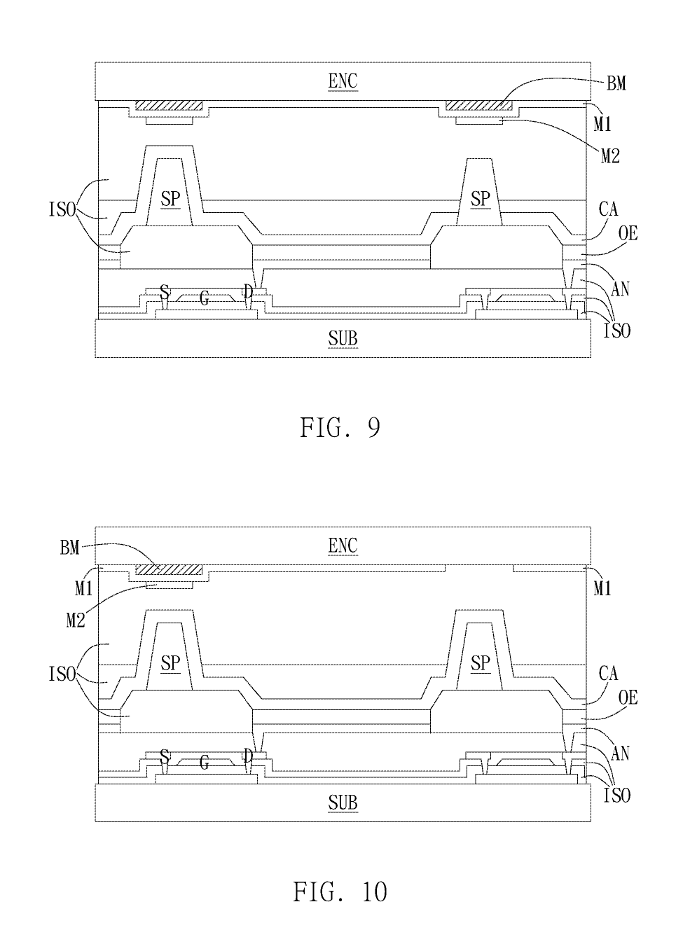

Please refer to FIG. 9. FIG. 9 illuminates the fifth embodiment of the laminated structure of the pixel of the in-cell touch panel of the invention.

As shown in FIG. 9, the laminated structure 9 includes a substrate SUB, an OLED layer OE, an encapsulation layer ENC, a spacer SP, a conductive layer M1, an anode layer AN, a cathode layer CA, an insulating layer ISO, a conductive layer M2 and a light-blocking layer BM. Wherein, the OLED layer OE is disposed above the substrate SUB. The encapsulation layer ENC is disposed above the OLED layer OE opposite to the substrate SUB. The conductive layer M1 is disposed on the lower surface of the encapsulation layer ENC and used as the touch sensing electrode of the in-cell touch panel. The anode layer AN and the cathode layer CA are disposed under and above the OLED layer OE respectively and used as the anode and the cathode of the OLED layer OE respectively. The light-blocking layer BM is disposed between the encapsulation layer ENC and the conductive layer M1; the conductive layer M2 is disposed on the lower surface of the conductive layer M1 and under the light-blocking layer BM, so that the conductive layer M2 can be shielded by the light-blocking layer BM. Since the conductive layer M2 is shielded by the light-blocking layer BM, the conductive layer M2 can be formed by transparent conductive material or opaque conductive material without specific limitations. The conductive layer M2 is coupled to the conductive layer M1 and used as traces of the touch sensing electrodes.

It should be noticed that, in the laminated structure 9 of this embodiment, the cathode layer CA disposed above the spacer SP at the right side has been removed and the cathode layer CA disposed above the spacer SP at the left side has been maintained, but not limited to this. The conductive layer M1 is entirely disposed on the lower surface of the encapsulation layer ENC and the conductive layer M2 is disposed above the spacer SP at the right side and the left side, namely the conductive layer M2 and the spacer SP at the right side and the left side are overlapped. Since the cathode layer CA disposed above the spacer SP at the right side has been removed, the parasitic capacitance between the conductive layer M2 and the cathode layer CA generated above the spacer SP at the right side in the prior arts can be effectively avoided in this embodiment; therefore, the RC loading of the in-cell touch panel can be effectively reduced and the touch performance of the in-cell touch panel can be also enhanced. As to the spacer SP at the left side, it is used as a control group of generating the parasitic capacitance. In fact, the cathode layer CA disposed above the spacer SP at the left side can be also removed to achieve better parasitic capacitance reducing effect, but not limited to this.

In practical applications, there can be an insulating layer formed between the conductive layer M1 and the conductive layer M2, and the conductive layer M1 and the conductive layer M2 are electrically connected through a via formed in the insulating layer. In addition, there can be no insulating layer between the conductive layer M1 and the conductive layer M2, and the conductive layer M1 and the conductive layer M2 can be electrically connected through a direct contacting way. Furthermore, the conductive layer M1 and the conductive layer M2 can be not electrically connected.

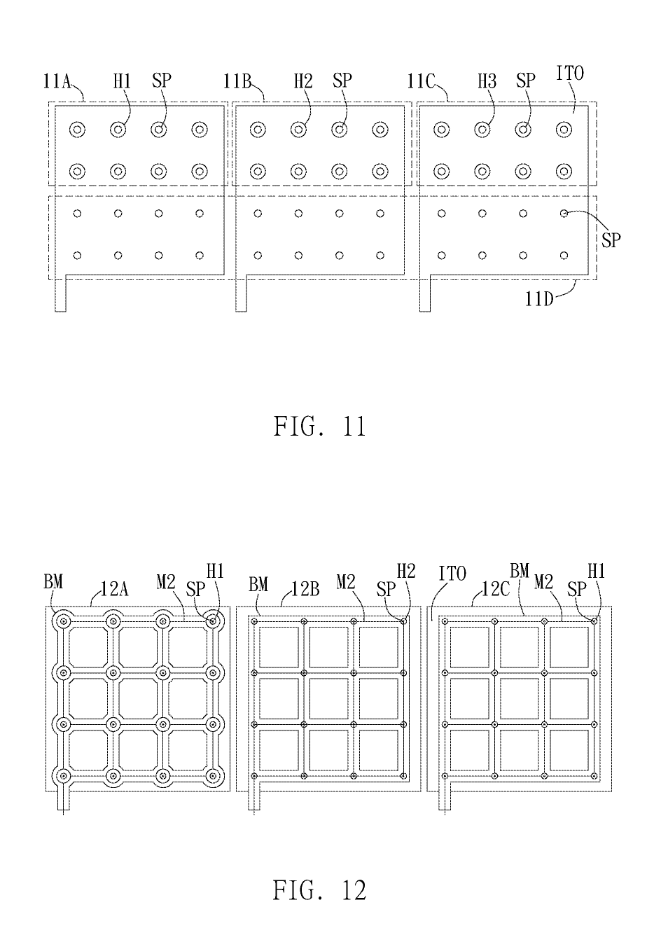

Please refer to FIG. 10. FIG. 10 illuminates the sixth embodiment of the laminated structure of the pixel of the in-cell touch panel of the invention.

As shown in FIG. 10, the laminated structure 10A includes a substrate SUB, an OLED layer OE, an encapsulation layer ENC, a spacer SP, a conductive layer M1, an anode layer AN, a cathode layer CA, an insulating layer ISO, a conductive layer M2 and a light-blocking layer BM. Wherein, the OLED layer OE is disposed above the substrate SUB. The encapsulation layer ENC is disposed above the OLED layer OE opposite to the substrate SUB. The conductive layer M1 is disposed on the lower surface of the encapsulation layer ENC and used as the touch sensing electrode of the in-cell touch panel. The anode layer AN and the cathode layer CA are disposed under and above the OLED layer OE respectively and used as the anode and the cathode of the OLED layer OE respectively. The light-blocking layer BM is disposed between the encapsulation layer ENC and the conductive layer M1; the conductive layer M2 is disposed on the lower surface of the conductive layer M1 and under the light-blocking layer BM, so that the conductive layer M2 can be shielded by the light-blocking layer BM. Since the conductive layer M2 is shielded by the light-blocking layer BM, the conductive layer M2 can be formed by transparent conductive material or opaque conductive material without specific limitations. The conductive layer M2 is coupled to the conductive layer M1 and used as traces of the touch sensing electrodes.

It should be noticed that, in the laminated structure 10 of this embodiment, the conductive layer M1 and the conductive layer M2 disposed above the spacer SP at the right side have been removed (namely no conductive layer M1 and conductive layer M2 is disposed above the spacer SP at the right side), and the conductive layer M1 disposed above the spacer SP at the left side has been maintained and the conductive layer M2 is disposed above the spacer SP at the left side, but not limited to this. The cathode layer CA entirely covers the spacer SP at the right side and the left side, namely the cathode layer CA and the spacer SP at the right side and the left side are overlapped. Since the conductive layer M1 and the conductive layer M2 disposed above the spacer SP at the right side have been removed, the parasitic capacitance between the conductive layer M2 and the cathode layer CA generated above the spacer SP at the right side in the prior arts can be effectively avoided in this embodiment; therefore, the RC loading of the in-cell touch panel can be effectively reduced and the touch performance of the in-cell touch panel can be also enhanced. As to the spacer SP at the left side, it is used as a control group of generating the parasitic capacitance. In fact, the conductive layer M1 and the conductive layer M2 disposed above the spacer SP at the left side can be also removed to achieve better parasitic capacitance reducing effect, but not limited to this.

In practical applications, there can be an insulating layer formed between the conductive layer M1 and the conductive layer M2, and the conductive layer M1 and the conductive layer M2 are electrically connected through a via formed in the insulating layer. In addition, there can be no insulating layer between the conductive layer M1 and the conductive layer M2, and the conductive layer M1 and the conductive layer M2 can be electrically connected through a direct contacting way. Furthermore, the conductive layer M1 and the conductive layer M2 can be not electrically connected.

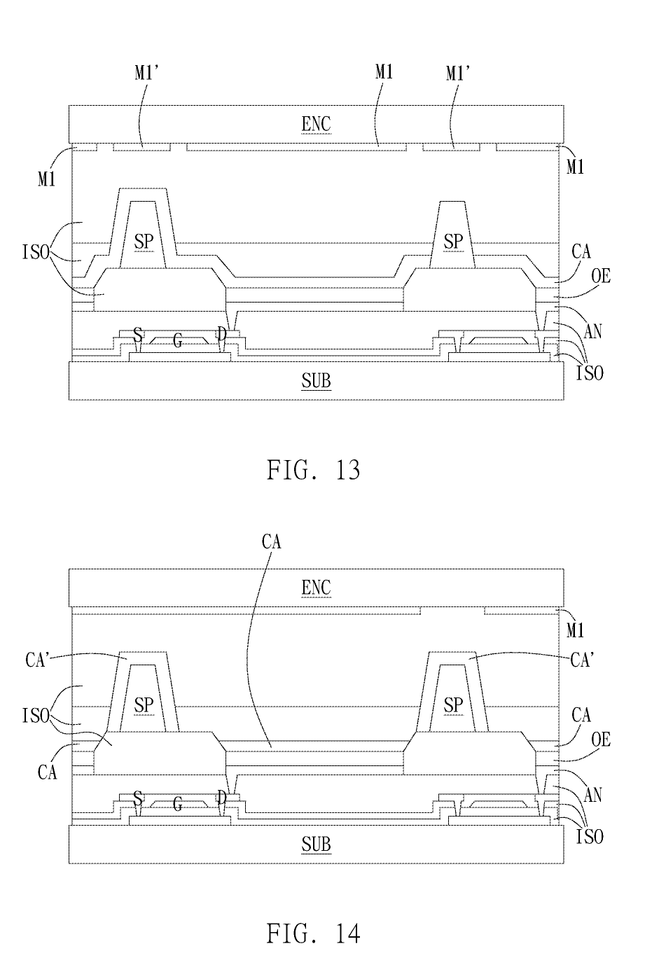

Then, please refer to FIG. 11 and FIG. 12. FIG. 11 and FIG. 12 illuminate different layout ways of traces in the in-cell touch panel of the invention respectively.

As shown in FIG. 11, in the area 11A, the touch sensing electrode overlapped by the spacer SP is removed and a hole H1 is left; in the area 11B, the first conductive layer overlapped by the spacer SP is removed and a hole H2 is left; in the area 11C, the first conductive layer and the touch sensing electrode overlapped by the spacer SP are both removed and a hole H3 is left; in the area 11D, a part of the first conductive layer and the touch sensing electrode overlapped by the spacer SP are maintained.

As shown in FIG. 12, in the area 12A, the touch sensing electrode overlapped by the spacer SP is removed and a hole H1 is left and the second conductive layer M2 will bypass the area of the spacer SP; in the area 12B, the first conductive layer overlapped by the spacer SP is removed and a hole H2 is left and the second conductive layer M2 will not bypass the area of the spacer SP; in the area 12C, the second conductive layer M2 and the touch sensing electrode overlapped by the spacer SP are removed and a hole H1 is left.

Except the above-mentioned embodiments, in order to keep the visual uniformity of the in-cell touch panel of the invention, instead of completely removing the first conductive layer disposed above the spacer SP and overlapped by the spacer SP, the first conductive layer disposed above the spacer SP and overlapped by the spacer SP can be separated from the first conductive layer used as the touch sensing electrode or the cathode of the OLED layer and maintained in the floating state.

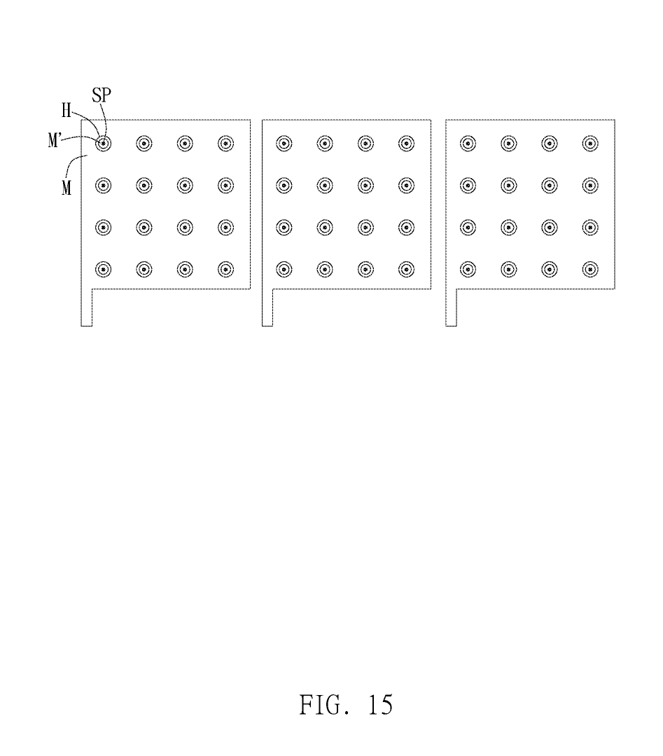

For example, as shown in FIG. 13, the conductive layer M1 formed on the lower surface of the encapsulation layer ENC is not disposed above the spacer SP and used as the touch sensing electrodes of the in-cell touch panel; the conductive layer M1′ formed on the lower surface of the encapsulation layer ENC and disposed above the spacer SP will be separated from the conductive layer M1 used as the touch sensing electrodes and maintained in the floating state; as shown in FIG. 14, the cathode layer CA′ formed above the spacer SP will be separated from the cathode layer CA used as the cathode of the OLED layer OE and maintained in the floating state.

Please refer to FIG. 15. FIG. 15 illuminates another layout way of traces in the in-cell touch panel of the invention. As shown in FIG. 15, the conductive layer M not overlapped by the spacer SP is used as the touch sensing electrodes or the cathode of the OLED layer. Since at least a part of the conductive layer M′ overlapped by the spacer SP is not removed, there will be still some conductive layer M′ within the hole H left, but the conductive layer M′ will be separated from the conductive layer M used as the touch sensing electrodes or the cathode of OLED layer and maintained in the floating state.

Above all, the in-cell touch panel of the invention has the following advantages and effects:

(1) The designs of touch electrodes and their traces are simple.

(2) The original aspect ratio of the in-cell touch panel is not affected by the layout of the invention.

(3) The RC loading of the touch electrodes can be effectively reduced.

(4) The module thickness of the AMOLED touch panel can be effectively reduced.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. An in-cell touch panel, comprising:
a plurality of pixels, a laminated structure of each pixel comprising:
a substrate;
an organic emissive layer formed above the substrate;
a spacer formed above the substrate with a specific distribution density; and
a first conductive layer formed above the organic emissive layer opposite to the substrate, wherein at least a part of the first conductive layer is not formed above the spacer.

2. The in-cell touch panel of claim 1, wherein the in-cell touch panel is an in-cell self-capacitive touch panel or an in-cell mutual-capacitive touch panel.

3. The in-cell touch panel of claim 1, wherein the first conductive layer is formed after the spacer.

4. The in-cell touch panel of claim 1, wherein the first conductive layer is formed by transparent conductive material.

5. The in-cell touch panel of claim 1, wherein the first conductive layer is used as a cathode of the organic emissive layer.

6. The in-cell touch panel of claim 5, wherein a part of the first conductive layer formed above the spacer is separated from the first conductive layer used as the cathode of the organic emissive layer and maintained in a floating state.

7. The in-cell touch panel of claim 1, wherein the first conductive layer is used as a touch sensing electrode of the in-cell touch panel.

8. The in-cell touch panel of claim 7, wherein a part of the first conductive layer formed above the spacer is separated from the first conductive layer used as the touch sensing electrode of the in-cell touch panel and maintained in a floating state.

9. The in-cell touch panel of claim 1, further comprising:
an encapsulation layer formed above the organic emissive layer and the spacer opposite to the substrate, wherein the first conductive layer is formed on the encapsulation layer.

10. The in-cell touch panel of claim 1, further comprising:
an encapsulation layer formed above the organic emissive layer and the spacer opposite to the substrate; and
a second conductive layer formed on the encapsulation layer.

11. The in-cell touch panel of claim 10, wherein the second conductive layer is used as a touch sensing electrode of the in-cell touch panel.

12. The in-cell touch panel of claim 10, wherein the second conductive layer is formed by transparent conductive material.

13. The in-cell touch panel of claim 10, wherein at least a part of the second conductive layer is not formed above the spacer.

14. The in-cell touch panel of claim 10, wherein the second conductive layer is formed above the spacer.

15. The in-cell touch panel of claim 10, further comprising:
a light-blocking layer formed on the encapsulation layer; and
a third conductive layer formed under the light-blocking layer.

16. The in-cell touch panel of claim 15, wherein the third conductive layer is coupled to the second conductive layer and used as traces of the touch sensing electrode.

17. The in-cell touch panel of claim 16, wherein an insulating layer is formed between the second conductive layer and the third conductive layer.

18. The in-cell touch panel of claim 17, wherein the second conductive layer and the third conductive layer are electrically connected through a via formed in the insulating layer.

19. The in-cell touch panel of claim 15, wherein there is no insulating layer between the second conductive layer and the third conductive layer, and the second conductive layer and the third conductive layer are electrically connected through a direct contacting way.

20. The in-cell touch panel of claim 15, wherein the second conductive layer and the third conductive layer are not electrically connected.

21. The in-cell touch panel of claim 15, wherein the light-blocking layer is formed above the spacer.

22. The in-cell touch panel of claim 21, wherein the second conductive layer and the third conductive layer are also formed above the spacer.

23. The in-cell touch panel of claim 15, wherein at least a part of the light-blocking layer is not formed above the spacer.

24. The in-cell touch panel of claim 15, wherein at least a part of the third conductive layer is not formed above the spacer.

25. The in-cell touch panel of claim 24, wherein at least a part of the second conductive layer is not formed above the spacer.

26. The in-cell touch panel of claim 24, wherein at least a part of the third conductive layer is routed bypassing the spacer.

27. The in-cell touch panel of claim 25, wherein at least a part of the second conductive layer and the third conductive layer is removed to reduce a RC loading of the in-cell touch panel.
